(19) United States
(12) Patent Application Publication
(10) Pub. No.: US 2026/0242922 A1
(43) Pub. Date: Aug. 20, 2026

(54) SUPPORT PLATE AND METHOD FOR MANUFACTURING SUPPORT PLATE

(71) Applicant: KYOCERA Corporation, Kyoto (JP)

(72) Inventor: Ryuto IIJIMA, Satsumasendai-shi, Kagoshima (JP)

(21) Appl. No.: 19/160,469

(22) PCT Filed: Mar. 11, 2024
(86) PCT No.: PCT/JP2024/009448

§ 371 Date: Aug. 28, 2025

(30) Foreign Application Priority Data
Mar. 27, 2023 (JP) 2023-050059

(51) Int. Cl. C23C 4/18; C01B 32/921; C23C 4/10

(52) U.S. Cl. CPC C23C 4/18; C01B 32/921; C23C 4/10

(57) ABSTRACT

A support plate includes a base and a coating layer. The base has a first surface and a second surface located on a side opposite to the first surface. The coating layer is located on the first surface and/or the second surface of the base. The coating layer contains metal carbide and/or semimetal carbide. The coating layer includes a central region including a center in a thickness direction and an outer surface region including an end portion on a surface side. The content ratio of the metal carbide and the semimetal carbide in mass % in the outer surface region is higher than the content ratio of the metal carbide and the semimetal carbide in mass % in the central region.

### CROSS-REFERENCE TO RELATED APPLICATION(S)

This application is a national stage application of International Application No. PCT/JP2024/009448, filed on Mar. 11, 2024, which designates the United States, and which is based upon and claims the benefit of priority to Japanese Patent Application No. 2023-050059, filed on Mar. 27, 2023.

### TECHNICAL FIELD

An embodiment of the disclosure relates to a support plate and a method for manufacturing a support plate.

### BACKGROUND OF INVENTION

A technique of manufacturing a cermet cutting tool has been known in which a metal carbide powder, a cobalt powder, and a nickel powder are crushed, mixed and molded, and this powder compact is subjected to firing (for example, see Patent Document 1). When the powder compact is fired, a support plate called a setter is used (for example, see Patent Document 2).

### CITATION LIST

### Patent Literature

Patent Document 1: JP 2016-052696 A
Patent Document 2: JP 2005-219943 A

### SUMMARY

In an aspect of an embodiment, a support plate includes a base and a coating layer. The base has a first surface and a second surface located on a side opposite to the first surface. The coating layer is located on the first surface and/or the second surface of the base. The coating layer contains metal carbide and/or semimetal carbide. The coating layer includes a central region and an outer surface region. The central region includes the center of the coating layer in a thickness direction. The outer surface region includes an end portion on the surface side of the coating layer. The content ratio of the metal carbide and the semimetal carbide in mass % in the outer surface region is higher than the content ratio of the metal carbide and the semimetal carbide in mass % in the central region.

### BRIEF DESCRIPTION OF THE DRAWINGS

FIG. 1 is a perspective view illustrating an example of a configuration of a support plate according to an embodiment.

FIG. 2 is a cross-sectional view illustrating an example of a configuration of the support plate according to the embodiment.

FIG. 3 is an enlarged view where the vicinity of a coating layer in the support plate illustrated in FIG. 2 is enlarged.

FIG. 4 is a cross-sectional view illustrating an example of a configuration of a support plate according to another embodiment.

FIG. 5 is a graph depicting a transition of a dimension of an inscribed circle in a cutting tool having been subjected to firing treatment on a support plate of Example.

FIG. 6 is a graph depicting a transition of a dimension of an inscribed circle in a cutting tool having been subjected to firing treatment on a support plate of Reference Example 3.

FIG. 7 is a graph depicting a result of an XPS analysis of a coating layer surface of the support plate of each of Example, Reference Example 1, and Reference Example 2.

FIG. 8 is a view illustrating an SEM image depicting an example of a crystal structure on an upper surface side of a sintered body having been subjected to firing treatment on the support plate of Example.

FIG. 9 is a view illustrating an SEM image depicting an example of a crystal structure on a lower surface side of the sintered body having been subjected to firing treatment on the support plate of Example.

FIG. 10 is a view illustrating an SEM image depicting an example of a crystal structure on an upper surface side of a sintered body having been subjected to firing treatment on the support plate of Reference Example 3.

FIG. 11 is a view illustrating an SEM image depicting an example of a crystal structure on a lower surface side of the sintered body having been subjected to firing treatment on the support plate of Reference Example 3.

### DESCRIPTION OF EMBODIMENTS

Hereinafter, an embodiment of a support plate and a method for manufacturing a support plate disclosed in the present application will be described. The present disclosure is not limited by the following embodiments.

In the technique of the related art described in Patent Document 1, in the firing treatment under a high temperature environment, a side reaction may occur between the powder compact and the support plate on which the powder compact is placed. This may cause degradation in quality of the cutting tool. In the technique of the related art described in Patent Document 2, a coating layer is formed by thermally spraying a powdery material containing titanium carbide as a main component.

In order to reduce the side reaction between the powder compact and the support plate on which the powder compact is placed, an increase in the content of titanium carbide in the coating layer is required. However, it has been found that simply increasing the content of titanium carbide in the coating layer reduces the durability of the coating layer. That is, since titanium carbide is weak against impact and rapid temperature change, the coating layer may be rapidly deteriorated when repeatedly used in the firing treatment under a high temperature environment.

A technique that can solve the above problem, obtain good durability in the support plate, and favorably maintain the quality of a supported body is expected to be implemented.

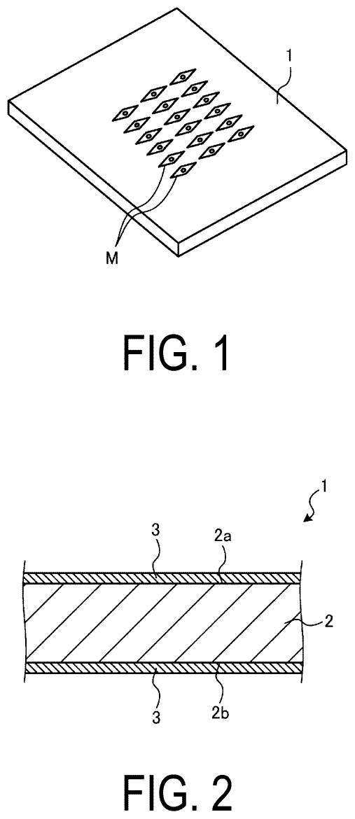

FIG. 1 is a perspective view illustrating an example of a configuration of a support plate 1 according to the embodiment. As illustrated in FIG. 1, the support plate 1 has a flat plate shape. Powder compacts M to be molded in a predetermined shape in a manufacturing process of a cutting tool are supported on a main surface of the support plate 1.

The powder compacts M are put into a firing furnace together with the support plate 1, and the powder compacts M are subjected to firing treatment. Thus, a sintered body (i.e., a cutting tool) is formed from the powder compacts M.

FIG. 1 illustrates an example in which the support plate 1 is formed in a flat plate shape, but the present disclosure is not limited thereto, and the support plate 1 may have any shape as long as a placement surface on which the powder compacts M can be placed is formed.

FIG. 1 illustrates an example in which the chip-shaped powder compacts M are placed on the support plate 1, but the present disclosure is not limited thereto, and powder compacts having various shapes such as a drill shape and a tap shape may be placed on the support plate 1.

FIG. 2 is a cross-sectional view illustrating an example of a configuration of the support plate 1 according to the embodiment. As illustrated in FIG. 2, the support plate 1 according to the embodiment includes a base 2 and a coating layer 3. The base 2 has a shape substantially equal to that of the support plate 1, and is formed in, for example, a flat plate shape.

The base 2 has a first surface 2a and a second surface 2b. The second surface 2b is located on the opposite side to the first surface 2a. For example, the first surface 2a is one main surface of the base 2, while the second surface 2b is another main surface of the base 2.

The coating layer 3 is located on the first surface 2a and/or the second surface 2b of the base 2. In the example of FIG. 2, the coating layer 3 is located on both the first surface 2a and the second surface 2b of the base 2. In the present disclosure, the coating layer 3 may cover the entire first surface 2a or second surface 2b, or the coating layer 3 may cover part of the first surface 2a or second surface 2b.

In the embodiment, the coating layer 3 may contain metal carbide and/or semimetal carbide. This can reduce the attachment of foreign matter to the sintered body (i.e., the cutting tool) after firing treatment, as compared with the case where the powder of the metal carbide is spread on the main surface of the base 2, then the powder compacts M (see FIG. 1) are placed on the support plate 1, and the powder compacts M are subjected to firing treatment.

A metal component constituting the metal carbide is not limited to a specific element. Examples of the metal component include titanium, nickel, cobalt, tungsten, and niobium. In particular, when the coating layer 3 contains carbide of these metal components generally used as a material of a cermet, a side reaction such as diffusion of the metal component from the powder compact to the support plate 1 is likely to be reduced, and thus the deterioration of the coating layer 3 is unlikely to progress.

A semimetal component constituting the semimetal carbide is not limited to a specific element. Examples of the semimetal component include boron, silicon, arsenic, tellurium, germanium, and antimony. Of these materials, silicon is available at a relatively low cost. Therefore, when silicon is used as the semimetal component, the support plate 1 can be produced at low cost.

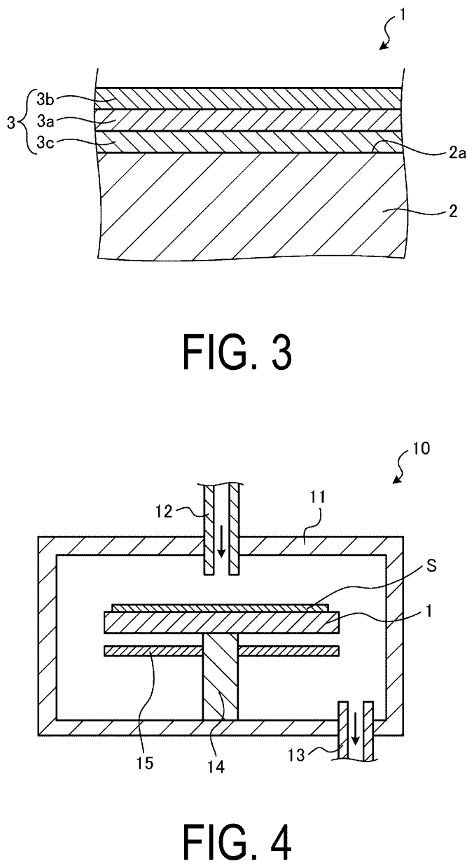

As illustrated in FIG. 3, the coating layer 3 is divided into three regions along the thickness direction. First, a middle region including the center in the thickness direction of the coating layer 3 is defined as a central region 3a. A region located closer to the base 2 than the central region 3a is defined as an inner surface region 3c. Finally, a region located farther from the base 2 than the central region 3a is defined as an outer surface region 3b. The inner surface region 3c includes an end portion of the coating layer 3 on a side in contact with the base 2. To rephrase, the inner surface region 3c includes a surface on the inner side of the coating layer 3. The outer surface region 3b includes an end portion on the outer surface side of the coating layer 3. To rephrase, the outer surface region 3b includes a surface on the outer side of the coating layer 3.

The thicknesses of the central region 3a, the inner surface region 3c, and the outer surface region 3b are not limited to specific values. In the present aspect, the thicknesses of the central region 3a, the inner surface region 3c, and the outer surface region 3b are set to the same value. That is, the coating layer 3 is divided into three regions having the same thickness, and these regions are defined as the central region 3a, the inner surface region 3c, and the outer surface region 3b.

Here, the content ratio of metal carbide and semimetal carbide contained in the coating layer 3 in mass % is defined as MA, the content ratio of metal carbide and semimetal carbide in mass % in the central region 3a is defined as M1, the content ratio of metal carbide and semimetal carbide in mass % in the outer surface region 3b is defined as M2, and the content ratio of metal carbide and semimetal carbide in mass % in the inner surface region 3c is defined as M3. In the case where the coating layer 3 contains metal carbide and semimetal carbide, the sum of the content ratio of the metal carbide in mass % and the content ratio of the semimetal carbide in mass % is referred to as the content ratio of the metal carbide and the semimetal carbide in mass %.

In the coating layer 3 according to the embodiment, the content ratio M2 in the outer surface region 3b may be higher than the content ratio M1 in the central region 3a. That is, the content ratio MA in the coating layer 3 does not simply take a large value. When the content ratio M1 in the central region 3a takes a relatively small value, the resistance of the coating layer 3 against impact and temperature change is increased, and the durability of the coating layer 3 can be improved. The content ratio M2 in the outer surface region 3b takes a relatively large value, thereby making it possible to reduce the attachment of foreign matter to a cutting tool having been subjected to firing treatment.

Thus, according to the embodiment, the quality of the sintered body is favorably maintained, so that a high-quality cutting tool can be manufactured.

The content ratio M3 in the inner surface region 3c may be higher than the content ratio M1 in the central region 3a. By making the content ratio M3 in the inner surface region 3c higher than the content ratio M1 in the central region 3a, in other words, by the content ratio M1 in the central region 3a being suppressed to be low, a difference in thermal expansion coefficient from the base 2 can be suppressed to be small, and thus the coating layer 3 is unlikely to peel off. Since the content ratio M3 in the inner surface region 3c is relatively high, the diffusion of carbon from the base 2 is likely to be reduced.

In addition, in the case where both the content ratio M2 in the outer surface region 3b and the content ratio M3 in the inner surface region 3c are higher than the content ratio M1 in the central region 3a, a difference in thermal expansion between the outer surface region 3b and the inner surface region 3c is likely to be suppressed. Therefore, the coating layer 3 is unlikely to warp due to a difference in thermal expansion, and the coating layer 3 is unlikely to peel off. From such a viewpoint, a calculation of (content ratio M2)/(content ratio M3) representing the ratio of the content ratio M2 to the content ratio M3 is desirably about 0.8 to 1.2.

On the other hand, the content ratio M2 in the outer surface region 3b may be higher than the content ratio M3 in the inner surface region 3c. In this case, the attachment of foreign matter to the cutting tool having been subjected to firing treatment can be reduced while suppressing the peeling of the coating film.

None of the content ratio M1 in the central region 3a, the content ratio M2 in the outer surface region 3b, and the content ratio M3 in the inner surface region 3c are limited to specific values. For example, the content ratio M1 may be 60 wt % to 97 wt %. The content ratio M2 and the content ratio M3 may each be 85 wt % to 100 wt %.

In the case where the content ratio M2 is higher than the content ratio M1, the ratio thereof (M1/M2) may be 0.6 to 0.95. In the case where the ratio M1/M2 is 0.6 or more, a situation in which the difference in thermal expansion between the central region 3a and the outer surface region 3b becomes excessively large can be suppressed. Because of this, cracks are unlikely to be formed inside the coating layer 3. In the case where the ratio M1/M2 is 0.95 or less, the effect of increasing the durability of the coating layer 3 by the central region 3a and the effect of reducing the attachment of foreign matter to the cutting tool by the outer surface region 3b can be favorably achieved.

In the case where the content ratio M3 is higher than the content ratio M1, the ratio thereof (M1/M3) may be 0.6 to 0.95. In the case where the ratio M1/M3 is 0.6 or more, a situation in which the difference in thermal expansion between the central region 3a and the inner surface region 3c becomes excessively large can be suppressed. Because of this, cracks are unlikely to be formed inside the coating layer 3. In the case where the ratio M1/M3 is 0.95 or less, both the effect of increasing the durability of the coating layer 3 by the central region 3a and the effect of reducing the diffusion of carbon from the base 2 by the inner surface region 3c can be favorably achieved.

In the embodiment, the coating layer 3 may include titanium carbide (TiC) and/or silicon carbide (SiC). This can reduce the adhesion of the sintered body after firing treatment to the support plate 1. Thus, according to the embodiment, the cutting tool can be stably manufactured.

In the present disclosure, the coating layer 3 is not limited to the case of containing titanium carbide and/or silicon carbide, and may contain, for example, tungsten carbide (WC), niobium carbide (NbC), or the like.

In the embodiment, when the surface of the coating layer 3 (i.e., the surface of the outer surface region 3b) is analyzed by X-ray photoelectron spectroscopy (XPS), a TiO₂ ratio calculated from a TiC value and a TiO₂ value determined from the observed peaks may be 0.2 or less.

The TiC value is a maximum value of intensity of emitted electrons per unit time at a peak in a range from 454 eV to 456 eV corresponding to Ti2P_{3/2} in the XPS spectrum of the surface of the coating layer 3.

The TiO₂ value is a maximum value of intensity of emitted electrons per unit time at a peak in a range from 457 eV to 459 eV corresponding to Ti2P_{3/2} in the XPS spectrum of the surface of the coating layer 3.

The TiO₂ ratio is calculated from a formula (1) given below.

TiO₂ ratio=TiO₂ value/(TiO₂ value+TiC value) (1)

As described above, by forming the coating layer 3 having a small content of titanium oxide (TiO₂) and a large content of titanium carbide, the adhesion of the sintered body after firing treatment to the support plate 1 can be reduced. Thus, according to the embodiment, the cutting tool can be stably manufactured.

In this case, the content ratio of TiC in mass % in the outer surface region 3b may be higher than the content ratio of TiC in the central region 3a in mass %. Since the content ratio of TiC in mass % in the outer surface region 3b takes a relatively large value, the attachment of foreign matter to the cutting tool having been subjected to firing treatment may be reduced. Since the content ratio of TiC in mass % in the central region 3a takes a relatively small value, the resistance of the coating layer 3 against impact and temperature change is increased, and the durability of the coating layer 3 may be improved.

The content ratio of TiO₂ in mass % in the outer surface region 3b may be lower than the content ratio of TiO₂ in mass % in the central region 3a. In this case, the content ratio of TiC in mass % in the outer surface region 3b is likely to be increased.

The content ratio of TiC in mass % in the inner surface region 3c may be higher than the content ratio of TiC in the central region 3a in mass %. By making the content ratio of TiC in mass % in the inner surface region 3c higher than the content ratio of TiC in mass % in the central region 3a, in other words, by the content ratio of TiC in mass % in the central region 3a being suppressed to be low, a difference in thermal expansion coefficient from the base 2 can be suppressed to be small, and thus the coating layer 3 is unlikely to peel off. Since the content ratio of TiC in mass % in the inner surface region 3c is relatively high, the diffusion of carbon from the base 2 is likely to be reduced.

In addition, in the case where both the content ratio of TiC in mass % in the outer surface region 3b and the content ratio of TiC in the inner surface region 3c in mass % are higher than the content ratio of TiC in mass % in the central region 3a, a difference in thermal expansion between the outer surface region 3b and the inner surface region 3c is likely to be suppressed. Therefore, the coating layer 3 is unlikely to warp due to a difference in thermal expansion, and the coating layer 3 is unlikely to peel off. From such a viewpoint, a ratio of (the content ratio of TiC in mass % in the outer surface region 3b)/(the content ratio of TiC in the inner surface region 3c in mass %) is desirably about 0.8 to 1.2.

The content ratio of TiO₂ in mass % in the inner surface region 3c may be lower than the content ratio of TiO₂ in mass % in the central region 3a. In this case, the content ratio of TiC in mass % in the inner surface region 3c is likely to be increased.

The content ratio of TiC in mass % in the outer surface region 3b may be higher than the content ratio of TiC in mass % in the inner surface region 3c. In this case, the attachment of foreign matter to the cutting tool having been subjected to firing treatment can be reduced while suppressing the peeling of the coating film.

In the embodiment, the base 2 may contain carbon as a main component. For example, the base 2 may be made of graphite. This can reduce the deterioration of the base 2 in the firing treatment of the powder compacts M under a high temperature environment. Thus, according to the embodiment, the cutting tool can be stably manufactured.

In the present disclosure, the base 2 is not limited to the case of being made of graphite. For example, the base 2 may be made of silicon nitride (Si₃N₄), silicon carbide, aluminum oxide (Al₂O₃), or the like. In the present disclosure, the base 2 may have a structure in which tungsten (W), molybdenum (Mo), or the like is disposed on a surface of a plate material made of graphite.

In the embodiment, the purity of the metal carbide and the semimetal carbide in the coating layer 3 may be 95% or more, and is preferably 99% or more. As described above, by forming the coating layer 3 having a large content of metal carbide and semimetal carbide, the adhesion of the sintered body after firing treatment to the support plate 1 can be reduced.

Thus, according to the embodiment, the cutting tool can be stably manufactured.

In the embodiment, the thickness of the coating layer 3 may be 20 μm to 200 μm, and is preferably 50 μm to 200 μm. This makes it possible to further reduce the adhesion of the sintered body after firing treatment to the support plate 1, and to manufacture the support plate 1 in a short time.

In the embodiment, surface roughness Sa of the coating layer 3 may be 10 μm to 50 μm, and is preferably 20 μm to 30 μm. This can further reduce the adhesion of the sintered body after firing treatment to the support plate 1. Thus, according to the embodiment, the cutting tool can be manufactured more stably.

In the embodiment, by increasing the surface roughness Sa of the coating layer 3 to be in a range from 10 μm to 50 μm, a reaction with a carbon-containing gas can be promoted in a manufacturing process of the support plate 1 to be described later.

In the embodiment described thus far, the support plate 1 configured to support the powder compacts M to become a cutting tool by being fired has been described, but the present disclosure is not limited to such example. FIG. 4 is a cross-sectional view illustrating an example of a configuration of a support plate 1 according to another embodiment.

As illustrated in FIG. 4, in the another embodiment, the support plate 1 may be used for supporting a sample S such as a semiconductor wafer inside a semiconductor manufacturing device 10. The semiconductor manufacturing device 10 may be, for example, a device that epitaxially grows a semiconductor crystal on the sample S utilizing a gas phase reaction, or may be, for example, a device that grows a semiconductor crystal using a metal organic chemical vapor deposition (MOCVD) method.

As illustrated in FIG. 4, the semiconductor manufacturing device 10 includes the support plate 1, a chamber 11, a gas supply path 12, a gas discharge path 13, a support column 14, and a heater 15. The support plate 1 has a disk shape, for example. The chamber 11 accommodates the support plate 1, the support column 14, and the heater 15.

The gas supply path 12 is connected between a gas supply unit (not illustrated) and the chamber 11, and supplies a gas supplied from the gas supply unit into the chamber 11. The gas supplied through the gas supply path 12 is a gas serving as a material of a semiconductor to be grown on the sample S.

The gas discharge path 13 is connected between a gas discharge unit (not illustrated) and the chamber 11, and discharges the atmosphere inside the chamber 11. The support column 14 is positioned to extend in the vertical direction, and supports the support plate 1 and the heater 15. The support plate 1 is supported by, for example, an upper end portion of the support column 14, and the heater 15 is supported by, for example, the support column 14 below the support plate 1.

The heater 15 heats the support plate 1, thereby heating the sample S supported by the support plate 1.

In the another embodiment, the support plate 1 configured to support the sample S in the semiconductor manufacturing device 10 includes the base 2 (see FIG. 2) and the coating layer 3 (see FIG. 2). The coating layer 3 is located on the first surface 2a (see FIG. 2) and/or the second surface 2b (see FIG. 2) of the base 2.

In the another embodiment, the coating layer 3 may contain metal carbide and/or semimetal carbide. For example, in the another embodiment, the coating layer 3 may contain silicon carbide.

This can reduce the attachment of foreign matter to the sample S during the semiconductor manufacturing process in the semiconductor manufacturing device 10. Thus, according to the another embodiment, the quality of the sample S is favorably maintained, so that a high-quality semiconductor element can be manufactured.

In the coating layer 3 according to the another embodiment, the content ratio M2 in the outer surface region 3b may be higher than the content ratio M1 in the central region 3a. With this, the resistance of the coating layer 3 against impact and temperature change is increased, and the durability of the coating layer 3 can be improved. The content ratio M2 in the outer surface region 3b takes a relatively large value, thereby making it possible to reduce the attachment of foreign matter to a cutting tool having been subjected to firing treatment.

### EXAMPLES

An example of the present disclosure will be specifically described below. In Example described below, a support plate in which graphite is used as a base and a coating layer containing titanium carbide as metal carbide or semimetal carbide is formed will be described, but the present disclosure is not limited to Example given below.

### Example

First, a base made of graphite and having a flat plate shape was prepared. Titanium (Ti) was thermally sprayed on the surface of the base to form a thermal spraying layer containing the titanium as a main component. The thickness of the thermal spraying layer was 50 μm. The thermal spraying treatment was performed by an atmospheric plasma spraying method.

The base on which the thermal spraying layer containing the titanium as a main component was formed was put into a heating furnace, and then the base was heated at a temperature of 1400° C. or higher while exhausting the inside of the heating furnace and supplying a carbon-containing gas into the heating furnace. In Example, a mixed gas of argon (Ar) and methane (CH₄) was used as the carbon-containing gas.

As a result, a carbon component derived from the carbon-containing gas was added from the surface side of the thermal spraying layer, and then the thermal spraying layer was changed to a coating layer containing titanium carbide. In the high-temperature heating treatment, a carbon component derived from the graphite of the base was added also from the back surface side of the thermal spraying layer, whereby the back surface side of the thermal spraying layer was also carbonized. In this manner, the support plate of Example was achieved.

### Reference Example 1

First, a base made of graphite and having a flat plate shape was prepared. Titanium (Ti) was thermally sprayed on the surface of the base to form a thermal spraying layer containing the titanium as a main component. The conditions of the thermal spraying treatment were the same as or similar to those in Example discussed above. In this manner, the support plate of Reference Example 1 was achieved.

### Reference Example 2

First, a base made of graphite and having a flat plate shape was prepared. Titanium (Ti) was thermally sprayed on the surface of the base to form a thermal spraying layer containing the titanium as a main component. The conditions of the thermal spraying treatment were the same as or similar to those in Example discussed above.

The base on which the thermal spraying layer of metal was formed was put into a heating furnace, and then the base was heated at a temperature of 1400° C. or higher while exhausting the inside of the heating furnace to obtain a vacuum therein.

As a result, oxygen atoms mixed into the thermal spraying layer during the thermal spraying treatment or the like were discharged, and a carbon component derived from the graphite of the base was added from the back surface side of the thermal spraying layer, whereby part of the thermal spraying layer was carbonized. In this manner, the support plate of Reference Example 2 was achieved.

### Reference Example 3

First, a base made of graphite and having a flat plate shape was prepared. The surface of the base was covered with powder of titanium carbide. In this manner, the support plate of Reference Example 3 was achieved.

### Various Evaluations

The support plates of Example and Reference Examples 1 to 3 achieved as described above were used to perform firing treatment on powder compacts. This firing treatment was performed in a manufacturing process of a cermet cutting tool. Various properties of the sintered bodies having been subjected to the firing treatment were evaluated to examine whether the firing treatment was favorably performed depending on the different support plates. The evaluation results are depicted in Table 1.

TABLE 1

| | | Reference | Reference | Reference |
|---|---|---|---|---|
| | Example | example 1 | example 2 | example 3 |
| Adhesion to support plate | None | Present | Present | None |
| Reaction to support plate | None | Present | Present | Present |
| | | (Foreign | (Pinhole | (Foreign |
| | | matter | generation) | matter |
| | | attachment) | | attachment) |
| Static properties of sintered body | A | — | — | A |
| Variation in dimension of sintered body | A | — | — | B |
| Cutting performance of sintered body | A | — | — | A |
| TiO₂ ratio of coating layer | 0.09 | 0.99 | 0.37 | — |

As depicted in Table 1, after the firing treatment, the adhesion of the sintered body was not observed with respect to the support plates of Example and Reference Example 3, whereas the adhesion of the sintered body was observed with respect to the support plates of Reference Example 1 and Reference Example 2.

As depicted in Table 1, after the firing treatment, the reaction of the sintered body with the support plate was not observed in Example, whereas the reaction of the sintered body with the support plate was observed in Reference Examples 1 to 3. Specifically, foreign matter was attached to the sintered body fired on the support plates of Reference Examples 1 and 3, and many pinholes were generated in the surface of the sintered body fired on the support plate of Reference Example 2.

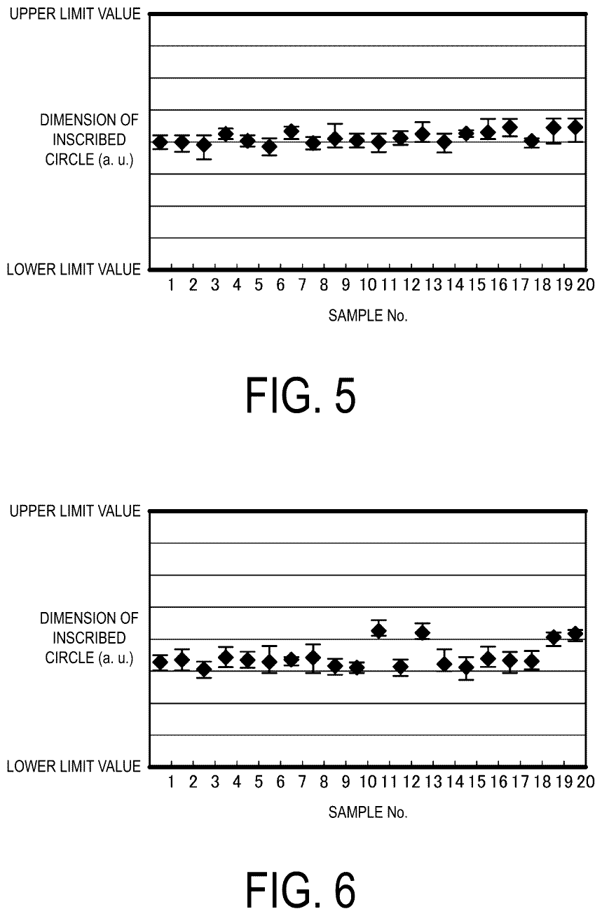

As depicted in Table 1, static properties of the sintered body were good (Evaluation A) in both Example and Reference Example 3. On the other hand, a variation in dimension of the sintered body was favorable (Evaluation A) in Example as depicted in FIG. 5, whereas a variation in dimension was slightly observed (Evaluation B) in Reference Example 3 as depicted in FIG. 6.

As depicted in Table 1, cutting performance of the sintered body (i.e., a cutting tool) was favorable (Evaluation A) in both Example and Reference Example 3.

The surface of the coating layer of the support plate achieved in each of Example, Reference Example 1, and Reference Example 2 was subjected to XPS analysis under the following measurement conditions by using an X-ray photoelectron spectrometer PHI Quantera II manufactured by ULVAC-PHI, Inc.

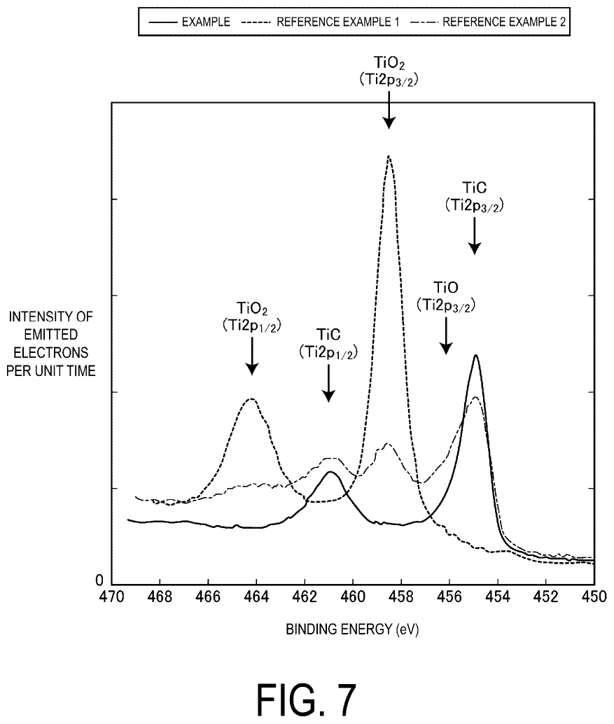

As the X-ray for irradiation, an Al Ku ray monochromatized by a monochromator was used. The output of the X-ray was 25 W, the acceleration voltage thereof was 15 kV, an area measured per time was a range of about 100 μm in diameter, a measurement interval of binding energy was 0.100 eV, and a measurement range of the binding energy was 450 eV to 470 eV. The results of the XPS analysis are depicted in FIG. 7.

FIG. 7 is a graph depicting a result of the XPS analysis of the coating layer surface of the support plate of each of Example, Reference Example 1, and Reference Example 2. As depicted in FIG. 7, peaks derived from TiO₂ occupy the most in the coating layer of the support plate of Reference Example 1, whereas peaks derived from TiO₂ decrease and peaks derived from TiC increase in the coating layer of the support plate of Reference Example 2.

In the coating layer of the support plate of Example, a peak derived from TiO₂ is hardly observed, whereas peaks derived from TiC occupy the most.

As described above, in the embodiment, the coating layer having a larger content of titanium carbide can be formed by carbonizing the thermal spraying layer from the surface side of the coating layer using the carbon-containing gas.

The carbon-containing gas according to the embodiment is not limited to the case of containing methane, and may contain another carbon compound gas such as acetylene (C₂H₂). On the other hand, by using methane, which is easy to handle, as the carbon-containing gas, carbonization treatment of the thermal spraying layer can be performed more easily.

The background was removed from each of the XPS spectra of Example, Reference Example 1, and Reference Example 2 depicted in FIG. 7. A maximum value of intensity of emitted electrons per unit time at a peak in a range from 454 eV to 456 eV corresponding to Ti2P_{3/2} in each XPS spectrum with the background being removed was calculated as the TiC value.

A maximum value of intensity of the emitted electrons per unit time at a peak in a range from 457 eV to 459 eV corresponding to Ti2P_{3/2} in each XPS spectrum with the background being removed was calculated as the TiO₂ value.

The TiO₂ ratio was calculated from the calculated TiC value and TiO₂ value based on the above formula (1). The calculation results are depicted in Table 1.

As depicted in Table 1, in the embodiment, by setting the TiO₂ ratio to 0.2 or less, the adhesion of the sintered body after firing treatment to the support plate can be reduced. Thus, according to the embodiment, the cutting tool can be stably manufactured.

As depicted in Table 1, in the embodiment, by setting the TiO₂ ratio to 0.2 or less, the reaction of the sintered body after firing treatment with the support plate can be reduced. Thus, according to the embodiment, the quality of the sintered body is favorably maintained, so that a high-quality cutting tool can be manufactured.

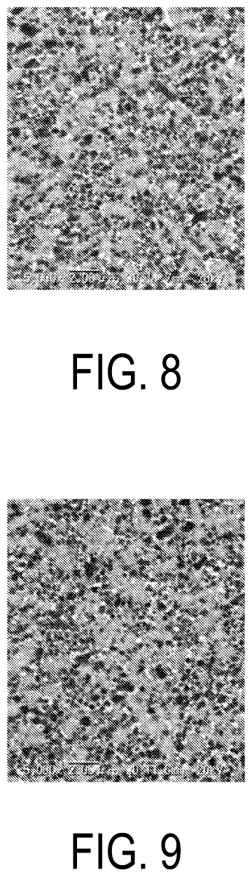

Surfaces of the upper surface (i.e., the side not facing the support plate) and the lower surface (i.e., the side facing the support plate) of the sintered body having been fired on the support plate of each of Example and Reference Example 3 were observed with a scanning electron microscope (SEM). The observation results are depicted in FIGS. 8 to 11.

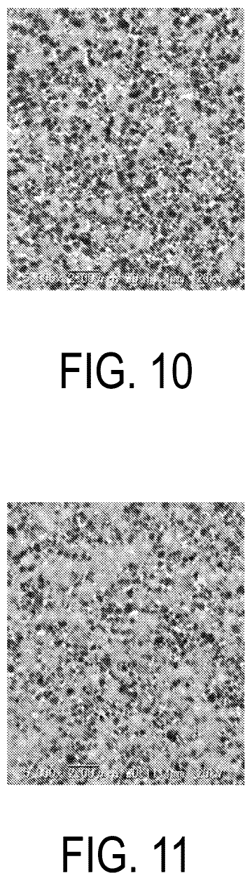

FIG. 8 and FIG. 9 are views illustrating SEM images depicting an example of a crystal structure on an upper surface side and a lower surface side of the sintered body having been subjected to firing treatment on the support plate of Example. FIG. 10 and FIG. 11 are views illustrating SEM images depicting an example of a crystal structure on the upper surface side and the lower surface side of the sintered body having been subjected to firing treatment on the support plate of Reference Example 3.

As depicted in FIGS. 8 and 9, the crystal structure of the upper surface and that of the lower surface are substantially uniform in the sintered body having been fired on the support plate of Example. On the other hand, as depicted in FIGS. 10 and 11, the crystal structure of the upper surface and that of the lower surface are slightly nonuniform in the sintered body having been fired on the support plate of Reference Example 3.

As described above, in the embodiment, the powder compacts are fired on the support plate on which the coating layer containing metal carbide is formed, whereby the crystal structure of the sintered body can be made to be more uniform.

Surface roughness Sa of the coating layer of the support plate achieved in Example was measured using the one-shot 3D profilometer VR-3000 manufactured by Keyence Corporation. As a result, the surface roughness Sa of the coating layer of the support plate of Example was 24 μm.

The purity of titanium carbide in the coating layer of the support plate achieved in Example was measured by a known method, and the purity was 95% or more.

Although the embodiments of the present disclosure have been described above, the present disclosure is not limited to the embodiments described above, and various changes can be made without departing from the spirit of the present disclosure.

For example, in the above embodiments, the example in which the support plate of the present disclosure is applied to a manufacturing process of a cutting tool made of cermet has been described, but the present disclosure is not limited to such example, and the support plate of the present disclosure may be applied to a manufacturing process of a cutting tool made of a cemented carbide alloy or the like.

In the above-described embodiments, the example in which a thermal spraying layer formed by thermal spraying treatment of a metal element (e.g., titanium) is carbonized to form a coating layer has been described, but the present disclosure is not limited to such example, and a metal layer or a semimetal layer formed by various known thin film forming methods may be carbonized to form a coating layer.

In the above-described embodiments, the example in which the technique of the present disclosure is applied to the semiconductor manufacturing device 10 configured to epitaxially grow a semiconductor crystal on the sample S by utilizing a gas phase reaction has been described, but the support plate of the present disclosure may be applied to devices used in other various semiconductor manufacturing processes.

Additional effects and other aspects can be easily derived by a person skilled in the art. Thus, a wide variety of aspects of the present disclosure are not limited to the specific details and representative embodiments represented and described above. Accordingly, various changes are possible without departing from the spirit or scope of the general inventive concepts defined by the appended claims and their equivalents.

Note that the present technique can also have the following configurations.

(1)
A support plate including:
a base having a first surface and a second surface located on a side opposite to the first surface; and
a coating layer located on the first surface and/or the second surface of the base,
in which the coating layer contains metal carbide and/or semimetal carbide,
the coating layer includes
   a central region including a center in a thickness direction, and
   an outer surface region including an end portion on a surface side, and
a content ratio of the metal carbide and the semimetal carbide in mass % in the outer surface region is higher than a content ratio of the metal carbide and the semimetal carbide in mass % in the central region.
   (2)
   The support plate according to (1) described above,
in which the coating layer contains titanium carbide and/or silicon carbide.
   (3)
   The support plate according to (1) or (2) described above,
in which the coating layer further includes an inner surface region including an end portion on a side in contact with the base, and
the content ratio of the metal carbide and the semimetal carbide in mass % in the inner surface region is higher than the content ratio of the metal carbide and the semimetal carbide in mass % in the central region.
   (4)
   The support plate according to (3) described above,
in which the content ratio of the metal carbide and the semimetal carbide in mass % in the outer surface region is higher than the content ratio of the metal carbide and the semimetal carbide in mass % in the inner surface region.
   (5)
   A support plate including:
a base having a first surface and a second surface located on a side opposite to the first surface; and
a coating layer located on the first surface and/or the second surface of the base,
in which the coating layer includes
   a central region including a center in a thickness direction, and
   an outer surface region including an end portion on a surface side,
the coating layer contains a Ti element,
in analyzing a surface of the outer surface region by X-ray photoelectron spectroscopy (XPS), when
   a maximum value of intensity of emitted electrons per unit time at a peak in a range from 454 eV to 456 eV corresponding to Ti2P_{3/2} is defined as a TiC value,
   a maximum value of intensity of emitted electrons per unit time at a peak in a range from 457 eV to 459 eV corresponding to Ti2P_{3/2} is defined as a TiO₂ value, and
   a ratio of the TiO₂ value to (the TiO₂ value+the TiC value) is defined as a TiO₂ ratio,
   the TiO₂ ratio is 0.2 or less, and
a content ratio of TiC in mass % in the outer surface region is higher than a content ratio of TiC in mass % in the central region.
   (6)
   The support plate according to (5) described above,
in which a content ratio of TiO₂ in mass % in the outer surface region is lower than a content ratio of TiO₂ in mass % in the central region.
   (7)
   The support plate according to (5) or (6) described above,
in which the coating layer further includes an inner surface region including an end portion on a side in contact with the base, and
the content ratio of TiC in mass % in the inner surface region is higher than the content ratio of TiC in mass % in the central region.
   (8)
   The support plate according to (7) described above,
in which the content ratio of TiO₂ in mass % in the inner surface region is lower than the content ratio of TiO₂ in mass % in the central region.
   (9)
   The support plate according to (7) or (8) described above,
in which the content ratio of TiC in mass % in the outer surface region is higher than the content ratio of TiC in mass % in the inner surface region.
   (10)
   The support plate according to any one of (1) to (9) described above,
in which the base contains carbon as a main component.
   (11)
   A method for manufacturing a support plate, the method including:
a step of forming a thermal spraying layer by thermally spraying metal and/or semimetal on a surface of a base having a plate shape and containing carbon as a main component; and
a step of forming a coating layer containing metal carbide and/or semimetal carbide by carbonizing the metal and/or the semimetal contained in the thermal spraying layer,
in which in the forming a coating layer, a carbon component is added to the thermal spraying layer from a surface side of the thermal spraying layer.
   (12)
   The method for manufacturing a support plate, according to (11) described above,
in which in the forming a coating layer, a carbon component is added to the thermal spraying layer by heating the base to 1400° C. or higher in presence of a carbon-containing gas.
   (13)
   The method for manufacturing a support plate, according to (12) described above,
in which the carbon-containing gas contains methane.
   (14)
   The method for manufacturing a support plate, according to (12) or (13) described above, in which in the forming a coating layer, the carbon-containing gas is supplied at a flow rate of 5 L/min or more.
   (15)
   The method for manufacturing a support plate, according to any one of (11) to (14) described above,
in which purity of the metal carbide and the semimetal carbide in the coating layer is 95% or more.
   (16)
   The method for manufacturing a support plate, according to any one of (11) to (15) described above,
in which the coating layer has a thickness in a range from 20 μm to 200 μm.
   (17)
   The method for manufacturing a support plate, according to any one of (11) to (16) described above,
in which surface roughness Sa of the coating layer is in a range from 10 μm to 50 μm.

1. A support plate comprising:
a base comprising a first surface and a second surface located on a side opposite to the first surface; and
a coating layer located on the first surface and/or the second surface of the base, wherein
the coating layer contains metal carbide and/or semimetal carbide,
the coating layer comprises
a central region including a center in a thickness direction, and
an outer surface region including an end portion on a surface side, and
a content ratio of the metal carbide and the semimetal carbide in mass % in the outer surface region is higher than a content ratio of the metal carbide and the semimetal carbide in mass % in the central region.

2. The support plate according to claim 1,
wherein the coating layer contains titanium carbide and/or silicon carbide.

3. The support plate according to claim 1, wherein
the coating layer further comprises an inner surface region including an end portion on a side in contact with the base, and
the content ratio of the metal carbide and the semimetal carbide in mass % in the inner surface region is higher than the content ratio of the metal carbide and the semimetal carbide in mass % in the central region.

4. The support plate according to claim 3, wherein
the content ratio of the metal carbide and the semimetal carbide in mass % in the outer surface region is higher than the content ratio of the metal carbide and the semimetal carbide in mass % in the inner surface region.

5. A support plate comprising:
a base comprising a first surface and a second surface located on a side opposite to the first surface; and
a coating layer located on the first surface and/or the second surface of the base, wherein
the coating layer comprises
a central region including a center in a thickness direction, and
an outer surface region including an end portion on a surface side,
the coating layer contains a Ti element,
in analyzing a surface of the outer surface region by X-ray photoelectron spectroscopy (XPS), when
a maximum value of intensity of emitted electrons per unit time at a peak in a range from 454 eV to 456 eV corresponding to Ti2P_{3/2} is defined as a TiC value,
a maximum value of intensity of emitted electrons per unit time at a peak in a range from 457 eV to 459 eV corresponding to Ti2P_{3/2} is defined as a TiO₂ value, and
a ratio of the TiO₂ value to (the TiO₂ value+the TiC value) is defined as a TiO₂ ratio,
the TiO₂ ratio is 0.2 or less, and
a content ratio of TiC in mass % in the outer surface region is higher than a content ratio of TiC in mass % in the central region.

6. The support plate according to claim 5,
wherein a content ratio of TiO₂ in mass % in the outer surface region is lower than a content ratio of TiO₂ in mass % in the central region.

7. The support plate according to claim 5,
wherein the coating layer further comprises an inner surface region comprising an end portion on a side in contact with the base, and
the content ratio of TiC in mass % in the inner surface region is higher than the content ratio of TiC in mass % in the central region.

8. The support plate according to claim 7,
wherein the content ratio of TiO₂ in mass % in the inner surface region is lower than the content ratio of TiO₂ in mass % in the central region.

9. The support plate according to claim 7,
wherein the content ratio of TiC in mass % in the outer surface region is higher than the content ratio of TiC in mass % in the inner surface region.

10. The support plate according to claim 1,
wherein the base contains carbon as a main component.

11. A method for manufacturing a support plate, the method comprising:
forming a thermal spraying layer by thermally spraying metal and/or semimetal on a surface of a base having a plate shape and containing carbon as a main component; and
forming a coating layer containing metal carbide and/or semimetal carbide by carbonizing the metal and/or the semimetal contained in the thermal spraying layer,
wherein in the forming a coating layer, a carbon component is added to the thermal spraying layer from a surface side of the thermal spraying layer.

12. The method for manufacturing a support plate, according to claim 11,
wherein in the forming a coating layer, a carbon component is added to the thermal spraying layer by heating the base to 1400° C. or higher in presence of a carbon-containing gas.

13. The method for manufacturing a support plate, according to claim 12,
wherein the carbon-containing gas contains methane.

14. The method for manufacturing a support plate, according to claim 12,
wherein in the forming a coating layer, the carbon-containing gas is supplied at a flow rate of 5 L/min or more.

15. The method for manufacturing a support plate, according to claim 11,
wherein purity of the metal carbide and the semimetal carbide in the coating layer is 95% or more.

16. The method for manufacturing a support plate, according to claim 11, wherein the coating layer has a thickness in a range from 20 μm to 200 μm.

17. The method for manufacturing a support plate, according to claim 11,
wherein surface roughness Sa of the coating layer is in a range from 10 μm to 50 μm.
